(19) United States
(12) Patent Application Publication
(10) Pub. No.: US 2026/0068413 A1
(43) Pub. Date: Mar. 5, 2026

(54) PEROVSKITE SOLAR CELL AND METHOD OF MANUFACTURING THE SAME

(71) Applicant: Hanwha Solutions Corporation, Seoul (KR)

(72) Inventors: HyungCheol BACK, Seongnam-si (KR); Geun Jin KIM, Seongnam-si (KR); Hyeongeun LEE, Seongnam-si (KR)

(73) Assignee: Hanwha Solutions Corporation, Seoul (KR)

(21) Appl. No.: 18/995,317

(22) PCT Filed: Feb. 6, 2023
(86) PCT No.: PCT/KR2023/001657

§ 371 Date: Nov. 19, 2025

(30) Foreign Application Priority Data
Mar. 7, 2022 (KR) 10-2022-0028853

(51) Int. Cl. H10K 30/86; H10K 30/10; H10K 30/40; H10K 30/50; H10K 71/12; H10K 85/10; H10K 85/50; H10K 102/00

(52) U.S. Cl. CPC H10K 30/86; H10K 30/10; H10K 30/40; H10K 30/50; H10K 71/12; H10K 85/10; H10K 85/50; H10K 2102/351

(57) ABSTRACT

The present invention relates to a perovskite solar cell and a method for manufacturing same, the perovskite solar cell having introduced thereinto a transparent conductive oxide layer comprising at least one of a semiconducting organic material having pi-orbital electrons between an electron transport layer and a source electrode, an organic material including elements having unshared electron pairs, and an organic material having ionic functional groups.

### TECHNICAL FIELD

The present invention relates to a perovskite solar cell, into which a transparent conductive oxide layer including one or more of a semiconducting organic material having pi-orbital electrons, an organic material containing elements having unshared electron pairs, and an organic material having an ionic functional group is introduced between an electron transport layer and a source electrode, and a method of manufacturing the same.

### BACKGROUND ART

In order to address the depletion of fossil energy and global environmental issues caused by the use of the fossil energy, studies are being actively conducted on renewable, clean, alternative energy sources such as solar energy, wind power, and hydroelectric power.

Among other things, there has been a significant increase in interest in solar cells that convert sunlight directly into electrical energy. In this case, the solar cell refers to a cell that generates current and voltage by using a photovoltaic effect that absorbs optical energy from sunlight and generates electrons and holes.

Currently, n-p diode-type silicon (Si) monocrystalline-based solar cells with optical energy conversion efficiency of more than 20% may be manufactured and actually used for photovoltaic power generation. There is also a solar cell using a compound semiconductor such as gallium arsenide (GaAs) with better conversion efficiency. However, the inorganic semiconductor-based solar cell requires a material purified to have very high purity to achieve high efficiency, a large amount of energy is consumed to purify raw materials, and expensive process devices are required for a process of manufacturing single crystals or thin films by using the raw materials. For this reason, there is a limitation in reducing costs required to manufacture the solar cells, and the limitation results in a barrier against large-scale adoption of the inorganic semiconductor-based solar cell.

Therefore, in order to manufacture the solar cells at low cost, it is necessary to significantly reduce the costs of materials or manufacturing processes that are mainly used for the solar cells. Studies are being conducted on perovskite solar cells capable of being manufactured with low-cost materials and processes, as an alternative to the inorganic semiconductor-based solar cells.

Recently, a perovskite solar cell, in which (NH₃CH₃)PbX₃ (X=I, Br, Cl), which is a halide with a perovskite structure, is used as a photoactivator, has been developed and being studied for commercialization. A general structural formula of a perovskite structure is an ABX₃ structure, in which an anion is positioned in position X, a cation with a large size is positioned at position A, and a cation with a small size is positioned at position B.

The perovskite solar cell, which is an organometallic halide with a molecular formula of (CH₃NH₃)PbX₃, was used as a photoactivator of a solar cell first in 2009. Since the development of a solid perovskite solar cell with the current structure in 2012, efficiency has been rapidly improved. A typical perovskite solar cell mainly uses a metal oxide as an electron transport layer and uses an organic material, such as spiro-OMETAD, or a polymer material as a hole transport layer (HTL). That is, a metal oxide porous film or thin film is manufactured on a transparent electrode, such as FTO, coated with a perovskite material, and coated with the hole transport layer, and then an electrode layer, such as gold (Au) or silver (Ag), is deposited.

In the perovskite solar cell, that is the organometallic halide with the molecular formula of (CH3NH3)PbX3, X in the molecular formula uses a halide ion such as I, Br, or Cl. In this case, an excess halide, which does not participate in the formation of the perovskite crystalline phase, may exist in the form of an ion defect and may not be fixed to a perovskite crystal, but escape from the crystal in the form of a halide bonded to hydrogen or a lightweight cation, thereby implementing high diffusibility. Therefore, after a Si/perovskite tandem element is manufactured, halide ions are easily diffused to surrounding layers without constraint by heating, light irradiation, or electrical external factors essentially included in subsequent module processes.

In particular, in case that the halide ions are diffused to the electrode layer, such as gold (Au) or silver (Ag), from the Si/perovskite tandem solar cell, a transparent electrode and a metal interface are corroded, which increases interface contact resistance. Further, a leak of metal ions into the solar cell element is caused by the corrosion of the metal electrode, which causes a problem in that performance of the solar cell element deteriorates.

### DISCLOSURE

### Technical Problem

An object of the present invention is to provide a perovskite solar cell, in which a transparent conductive oxide layer, which includes one or more of a semiconducting organic material having a pi-orbital electron, an organic material containing an element having an unshared electron pair, and an organic material having an ionic functional group, is introduced between an electron transport layer and a source electrode, such that light transmission properties with respect to wavelengths of 350 to 1200 nm are not greatly changed, and surface resistance is not also greatly changed, thereby minimizing a deterioration in performance of the perovskite solar cell and ensuring stability, and a method of manufacturing the same.

### Technical Solution

In order to achieve the above-mentioned object, a perovskite solar cell of the present invention includes: a stack in which a hole transport layer, a perovskite light absorption layer, an electron transport layer, and a source electrode are sequentially stacked.

In the exemplary embodiment of the present invention, a transparent conductive oxide layer may be formed between the source electrode and the electron transport layer.

In the exemplary embodiment of the present invention, the transparent conductive oxide layer may include one or more of a semiconducting organic material having a pi-orbital electron, an organic material containing an element having an unshared electron pair, and an organic material having an ionic functional group.

In the exemplary embodiment of the present invention, the transparent conductive oxide layer may have a structure in which a first transparent conductive oxide layer, a functional organic material layer, and a second transparent conductive oxide layer are sequentially stacked.

In the exemplary embodiment of the present invention, the first transparent conductive oxide layer may be a transparent thin-film on which indium tin oxide (ITO), fluorine doped tin oxide (FTO), Sb₂O₃ doped tin oxide (ATO), gallium doped tin oxide (GTO), tin doped zinc oxide (ZTO), gallium doped ZTO (ZTO:Ga), indium gallium zinc oxide (IGZO), indium doped zinc oxide (IZO), or aluminum doped zinc oxide (AZO) is deposited.

In the exemplary embodiment of the present invention, the second transparent conductive oxide layer may be a transparent thin-film on which indium tin oxide (ITO), fluorine doped tin oxide (FTO), Sb₂O₃ doped tin oxide (ATO), gallium doped tin oxide (GTO), tin doped zinc oxide (ZTO), gallium doped ZTO (ZTO:Ga), indium gallium zinc oxide (IGZO), indium doped zinc oxide (IZO), or aluminum doped zinc oxide (AZO) is deposited.

In the exemplary embodiment of the present invention, the functional organic material layer may be a thin film on which the semiconducting organic material having the pi-orbital electron, the organic material containing the element having the unshared electron pair, or the organic material having the ionic functional group is deposited.

In the exemplary embodiment of the present invention, the semiconducting organic material having the pi-orbital electron may include one or more selected from fullerene, a fullerene-based derivative, perylene diimide (PDI), and naphthalene diimide (NDI).

In the exemplary embodiment of the present invention, the organic material containing the element having the unshared electron pair may be an organic material containing one or more elements selected from oxygen, nitrogen, and phosphorus.

In the exemplary embodiment of the present invention, the organic material having the ionic functional group may include one or more selected from polyethylenimine ethoxylated (PEIE) and PFN (poly[(9, 9-di(3,3′-N,N′-trimethyl-ammonium) propylfluorenyl-2,7-diyl)-alt-co-(9,9-dioctylfluorenyl-2,7-diyl)] diiodide salt).

In the exemplary embodiment of the present invention, the first transparent conductive oxide layer and the functional organic material layer may have a thickness ratio of 1:0.05 to 0.15.

In the exemplary embodiment of the present invention, the second transparent conductive oxide layer and the functional organic material layer may have a thickness ratio of 1:0.05 to 0.15.

In the exemplary embodiment of the present invention, the first transparent conductive oxide layer may have an average thickness of 5 to 100 nm.

In the exemplary embodiment of the present invention, the functional organic material layer may have an average thickness of 2 to 50 nm.

In the exemplary embodiment of the present invention, the second transparent conductive oxide layer may have an average thickness of 5 to 100 nm.

In the exemplary embodiment of the present invention, the perovskite solar cell may be a p-i-n structured perovskite solar cell, an n-i-p inverse structured perovskite solar cell, a tandem perovskite solar cell, or a tandem silicon/perovskite heterojunction solar cell.

In the exemplary embodiment of the present invention, the transparent conductive oxide layer may have light transmittance of 70 to 99% with respect to a wavelength of 350 to 1200 nm and have surface resistance of 5 to 500 Ω/sq.

Meanwhile, a method of manufacturing a perovskite solar cell of the present invention may include: a first step of forming a transparent conductive oxide layer, by a deposition process, on an electron transport layer of a stack in which a hole transport layer, a perovskite light absorption layer, and the electron transport layer are sequentially stacked; and a second step of forming a source electrode on the transparent conductive oxide layer, in which the transparent conductive oxide layer includes one or more of a semiconducting organic material having a pi-orbital electron, an organic material containing an element having an unshared electron pair, and an organic material having an ionic functional group.

In the exemplary embodiment of the present invention, the first step may include: a first-first step of forming a first transparent conductive oxide layer, by the deposition process, on the electron transport layer of the stack in which the hole transport layer, the perovskite light absorption layer, and the electron transport layer are sequentially stacked; a first-second step of forming a functional organic material layer on the first transparent conductive oxide layer by a deposition or solution process; and a first-third step of forming a second transparent conductive oxide layer on the functional organic material layer by the deposition process.

Meanwhile, a tandem silicon/perovskite heterojunction solar cell of the present invention may include: a stack in which a drain electrode, a silicon solar cell, a recombination layer, a hole transport layer, a perovskite light absorption layer, an electron transport layer, and a source electrode are sequentially stacked, in which a transparent conductive oxide layer is formed between the source electrode and the electron transport layer, and in which the transparent conductive oxide layer includes one or more of a semiconducting organic material having a pi-orbital electron, an organic material containing an element having an unshared electron pair, and an organic material having an ionic functional group.

### Advantageous Effects

In the perovskite solar cell of the present invention, the perovskite solar cell, in which the transparent conductive oxide layer, which includes one or more of the semiconducting organic material having the pi-orbital electrons, the organic material containing the element having the unshared electron pair, and the organic material having the ionic functional group, is introduced between the electron transport layer and the source electrode, such that it is possible to prevent in advance a situation in which halide anions diffused from the perovskite light absorption layer to the source electrode interface made of a metallic material corrodes the source electrode interface, thereby improving the lifespan. In addition, the optical characteristics may be changed, and the anti-reflection properties may be implemented, thereby improving the performance.

### DESCRIPTION OF DRAWINGS

FIG. 1 is a cross-sectional view illustrating a transparent conductive oxide layer according to an exemplary embodiment of the present invention.

FIG. 2 is a graph illustrating a result of measuring light transmittance of transparent conductive oxide films prepared in Preparation Example 1, Preparation Example 2, and Comparative Preparation Example 1.

### MODES OF THE INVENTION

Hereinafter, the present invention will be described more specifically.

A perovskite solar cell in the related art suffers from a problem in which halide anions diffused from a perovskite light absorption layer corrodes a source electrode interface made of a metallic material, which causes an increase in interface contact resistance, and the corrosion of the source electrode made of a metallic material causes a leak of metal ions into the perovskite solar cell, which degrades performance of the perovskite solar cell.

Therefore, the present invention relates to a perovskite solar cell, in which a transparent conductive oxide layer, which includes one or more of a semiconducting organic material having pi-orbital electrons, an organic material containing an element having an unshared electron pair, and an organic material having an ionic functional group, is introduced between an electron transport layer and a source electrode, such that it is possible to prevent in advance a situation in which halide anions diffused from the perovskite light absorption layer to the source electrode interface made of a metallic material corrodes the source electrode interface, thereby improving the lifespan. Further, the optical characteristics may be changed, and the anti-reflection properties may be implemented, thereby improving the performance.

The perovskite solar cell of the present invention may be a p-i-n structured perovskite solar cell, an n-i-p inverse structured perovskite solar cell, a tandem perovskite solar cell, or a tandem silicon/perovskite heterojunction solar cell, particularly, a tandem silicon/perovskite heterojunction solar cell. The perovskite solar cell of the present invention is a solar cell including a stack having a structure in which a hole transport layer (HTL), a perovskite light absorption layer, an electron transport layer (ETL), a transparent conductive oxide layer, and a source electrode are sequentially stacked.

In the exemplary embodiment, in case that the perovskite solar cell of the present invention is a tandem silicon/perovskite heterojunction solar cell, the perovskite solar cell may include a structure in which a drain electrode, a silicon solar cell, a recombination layer, and the stack are sequentially stacked. Specifically, in case that the perovskite solar cell of the present invention is a tandem silicon/perovskite heterojunction solar cell, the perovskite solar cell may include a structure in which a drain electrode, a silicon solar cell, a recombination layer, a hole transport layer, a perovskite light absorption layer, an electron transport layer, a transparent conductive oxide layer, and a source electrode are sequentially stacked.

The hole transport layer (HTL) may include an inorganic and/or organic hole transport material.

In this case, the inorganic hole transport material may include one or more selected from nickel oxide (NiOx), MoOx, CuSCN, CuCrO₂, CuL, MoO, and V₂O₅.

In addition, the organic hole transport material may include one or more selected from a carbazole derivative, a polyarylalkane derivative, a phenylenediamine derivative, an arylamine derivative, an amino-substituted chalcone derivative, a styrylanthracene derivative, a fluorene derivative, a hydrazone derivative, a stilbene derivative, a silazane derivative, an aromatic tertiary amine compound, a styrylamine compound, an aromatic dimethylidene compound, a porphyrin compound, a phthalocyanine compound, a polytiophene derivative, a polypyrrole derivative, a polyparaphenylenevinylene derivative, pentacene, coumarin 6 (3-(2-benzothiazolyl)-7-(diethylamino)coumarin), ZnPC (zinc phthalocyanine), CuPC (copper phthalocyanine), TiOPC (titanium oxide phthalocyanine), Spiro-MeOTAD(2,2′,7,7′-tetrakis (N,N-p-dimethoxyphenylamino)-9,9′-spirobifluorene), F16CuPC (copper(II) 1,2,3,4,8,9,10,11,15,16,17,18,22,23,24,25-hexadecafluoro-29H,31H-phthalocyanine), SubPc (boron subphthalocyanine chloride), and N3 (cis-di(thiocyanato)-bis(2,2′-bipyridyl-4,4′-dicarboxylic acid)-ruthenium(II), P3HT (poly[3-hexylthiophene]), MDMO-PPV (poly[2-methoxy-5-(3′,7′-dimethyloctyloxyl)]-1,4-phenylene vinylene), MEH-PPV (poly[2-methoxy-5-(2″-ethylhexyloxy)-p-phenylene vinylene]), P3OT (poly(3-octyl thiophene)), POT (poly(octyl thiophene)), P3DT (poly(3-decyl thiophene)), P3DDT (poly(3-dodecyl thiophene), PPV (poly(p-phenylene vinylene)), TFB (poly(9,9′-dioctylfluorene-co-N-(4-butylphenyl)diphenyl amine), polyaniline, Spiro-MeOTAD ([2,22′,7,77′-tetrkis (N,N-di-pmethoxyphenyl amine)-9,9,9′-spirobi fluorine]), PCPDTBT (Poly[2,1,3-benzothiadiazole-4,7-diyl[4,4-bis(2-ethylhexyl-4H-cyclopenta [2,1-b:3,4-b′]dithiophene-2,6-diyl]], Si-PCPDTBT (poly[(4,4′-bis(2-ethylhexyl)dithieno[3,2-b:2′,3′-d]silole)-2,6-diyl-alt-(2,1,3-benzothiadiazole)-4,7-diyl]), PBDTTPD (poly((4,8-diethylhexyloxyl), PFDTBT (poly[2,7-(9-(2-ethylhexyl)-9-hexyl-fluorene)-alt-5,5-(4′,7,-di-2-thienyl-2′,1′,3′-benzothiadiazole)]), PFO-DBT (poly[2,7.9,9-(dioctyl-fluorene)-alt-5,5-(4′,7′-di-2.thienyl-2′,1′,3′-benzothiadiazole)]), PSiFDTBT (poly[(2,7-dioctylsilafluorene)-2,7-diyl-alt-(4,7-bis(2-thienyl)-2,1,3-benzothiadiazole)-5,5′-diyl]), PCDTBT (Poly [[9-(1-octylnonyl)-9H-carbazole-2,7-diyl]-2,5-thiophenediyl-2,1,3-benzothiadiazole-4,7-diyl-2,5-thiophenediyl]), PFB (poly(9,9′-dioctylfluorene-co-bis(N,N′-(4,butylphenyl))bis(N,N′-phenyl-1,4-phenylene)diamine), F8BT (poly(9,9′-dioctylfluorene-cobenzothiadiazole), PEDOT (poly(3,4-ethylenedioxythiophene)), PEDOT:PSS poly(3,4-ethylenedioxythiophene) poly(styrenesulfonate), PTAA (poly(triarylamine)), 2-PACz, 4-PACz, MeO-2PACz, Br-2PACz, Me-4PACz, MeO-4PACz, and 6-PACz.

In addition, examples of methods of forming the hole transport layer may include application and vacuum deposition methods. The application methods may include gravure application, bar application, printing, spraying, spin coating, dipping, and die coating. The vacuum deposition methods may include thermal deposition, E-beam deposition, sputter deposition, and ALD deposition.

The perovskite light absorption layer may include a general perovskite material applied to a light absorption layer of the solar cell. In a preferred example, the perovskite light absorption layer may contain a perovskite material represented by Chemical Formula 1 below.

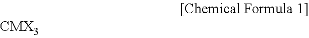

In Chemical Formula 1, C is a monovalent cation, which may include amine, ammonium, monovalent metal, bivalent metal, and/or another cation or cation-like compound, preferably, formamidinium (FA), methylammonium (MA), FAMA, CsFAMA, CsFA, or N(R)₄⁺ (in which R may be the same or different groups, and in which R is a straight-chain alkyl group of carbon number 1 to 5, a crushed alkyl group of carbon number 3 to 5, a phenyl group, an alkylphenyl group, an alkoxyphenyl group, or an alkyl halide).

In addition, in Chemical Formula 1, M is a divalent cation that may include one or two selected from Fe, Co, Ni, Cu, Sn, Pb, Bi, Ge, Ti, Eu, and Zr.

In addition, in Chemical Formula 1, X is a monovalent anion that may include one or more halide elements and/or hexavalent anions selected from F, Cl, Br, and I. In a preferred example, X may be IₓBr₃₋ₓ (0≤x≤3).

Further, in a preferred embodiment of Chemical Formula 1, FAPbIₓBr₃₋ₓ (0≤x≤3), MAPbIₓBr₃₋ₓ (0≤x≤3), CSMAFAPbIₓBr₃₋ₓ (0≤x≤3), CH₃NH₃PbX₃ (X=Cl, Br, I, BrI₂, or Br₂I), CH₃NH₃SnX₃ (X=Cl, Br, or I), CH(═NH)NH₃PbX₃ (X=Cl, Br, I, BrI₂, or Br₂I), or CH(═NH)NH₃SnX₃ (X=Cl, Br, or I).

Meanwhile, in the perovskite solar cell of the present invention, the perovskite light absorption layer may be a single layer made of the same perovskite material or may have a multilayer structure in which a plurality of layers made of different perovskite materials is stacked. The perovskite light absorption layer may include another type of perovskite material, which has a pillar shape, such as a column shape, a plate shape, a needle shape, a wire shape, or a rod shape and is different from one type of perovskite material, in a light absorption layer made of one type of perovskite material.

In addition, examples of methods of forming the perovskite light absorption layer may include application and vacuum deposition methods. The application methods may include gravure application, bar application, printing, spraying, spin coating, dipping, inkjet application, die coating, and the like.

The electron transport layer (ETL) may include an organic and/or inorganic hole transport material.

In this case, the organic electron transport material may include one or more selected from C₆₀, C₇₀, PC60BM, PC70BM, BCP, and PEIE.

In addition, the inorganic electron transport material may include one or more of semiconducting metal oxides such as titanium oxide (TiO₂), SnO, and ZnO.

In addition, examples of methods of forming the electron transport layer may include a vacuum dispersion method and a solution dispersion method. The vacuum deposition methods may include thermal deposition, E-beam deposition, sputter deposition, ALD deposition, and the like. The solution application methods may include gravure application, bar application, printing, spraying, spin coating, dipping, die coating, and the like.

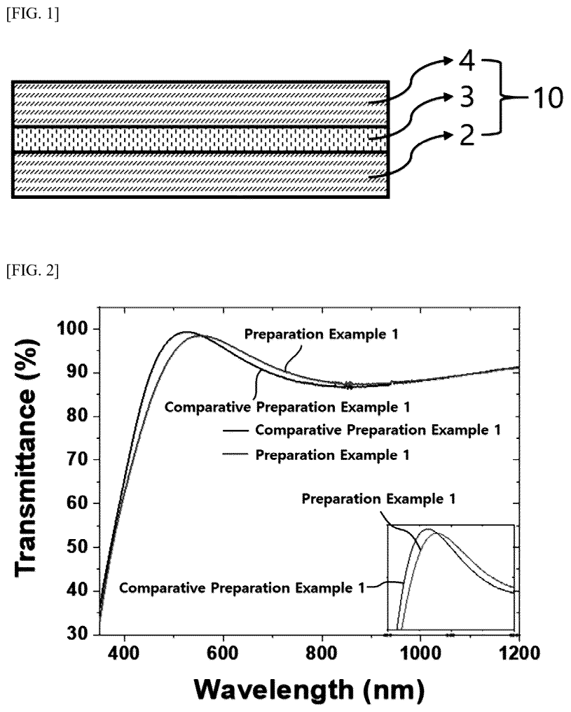

With reference to FIG. 1, a transparent conductive oxide layer 10 may be formed on an electron transport layer by a deposition process or a solution process.

In this case, a general deposition process used in the art may be used as the deposition, and particularly, a vacuum deposition process may be performed. In addition, the solution process may be performed by a spin coating process.

In addition, the transparent conductive oxide layer 10 may include one or more of the semiconducting organic material having the pi-orbital electrons, the organic material containing the element having the unshared electron pair, and the organic material having the ionic functional group.

Specifically, the transparent conductive oxide layer 10 may have a structure in which a first transparent conductive oxide layer 2, a functional organic material layer 3, and a second transparent conductive oxide layer 4 are sequentially stacked. Particularly, the transparent conductive oxide layer 10 may include one or more selected from the organic material capable of reducing surface energy when the second transparent conductive oxide layer 4 is deposited on the functional organic material layer 3, specifically, a semiconducting organic material having pi-orbital electrons, the organic material containing the element having the unshared electron pair, and the organic material having the ionic functional group. In other words, the transparent conductive oxide layer 10 may have the structure in which the first transparent conductive oxide layer 2, the functional organic material layer 3, and the second transparent conductive oxide layer 4 are sequentially stacked by forming the first transparent conductive oxide layer 2 on the electron transport layer by a deposition process, forming the functional organic material layer 3 on the first transparent conductive oxide layer 2 by a deposition or solution process, and forming the second transparent conductive oxide layer 4 on the functional organic material layer 3 by a deposition process.

Meanwhile, the first transparent conductive oxide layer 2 may be a transparent thin-film on which indium tin oxide (ITO), fluorine doped tin oxide (FTO), Sb₂O₃ doped tin oxide (ATO), gallium doped tin oxide (GTO), tin doped zinc oxide (ZTO), gallium doped ZTO (ZTO:Ga), indium gallium zinc oxide (IGZO), indium doped zinc oxide (IZO), or aluminum doped zinc oxide (AZO) is deposited.

In addition, the second transparent conductive oxide layer 4 may be a transparent thin-film on which indium tin oxide (ITO), fluorine doped tin oxide (FTO), Sb₂O₃ doped tin oxide (ATO), gallium doped tin oxide (GTO), tin doped zinc oxide (ZTO), gallium doped ZTO (ZTO:Ga), indium gallium zinc oxide (IGZO), indium doped zinc oxide (IZO), or aluminum doped zinc oxide (AZO) is deposited.

In addition, the functional organic material layer 3 may be a thin film on which the semiconducting organic material having the pi-orbital electrons, the organic material containing the element having the unshared electron pair, or the organic material having the ionic functional group is deposited.

In this case, the semiconducting organic material having the pi-orbital electrons may include one or more selected from fullerene, a fullerene-based derivative, perylene diimide (PDI), and naphthalene diimide (NDI). In a specific example, the fullerene may include one or more selected from C₆₀ fullerene and C₇₀ fullerene, and the fullerene-based derivative may include phenyl-C61-butyric acid methylester (PCBM).

In addition, the organic material containing the element having the unshared electron pair may be an organic material containing one or more elements selected from oxygen, nitrogen, and phosphorus. In a specific example, the organic material containing the element having the unshared electron pair may include one or more selected from crown ether and porphyrin series derivatives.

In addition, the semiconducting organic material having the ionic functional group may include an organic material that may exist in the form of salt and may be deposited. Particularly, the semiconducting organic material may include one or more selected from polyethylenimine ethoxylated (PEIE) and PFN (Poly[(9,9-di(3,3′-N,N′-trimethyl-ammonium)propylfluorenyl-2,7-diyl)-alt-co-(9,9-dioctylfluorenyl-2,7-diyl)] diiodide salt).

Specifically, the first transparent conductive oxide layer 2 and the functional organic material layer 3 may have a thickness ratio of 1:0.05 to 0.15, particularly a thickness ratio of 1:0.066 to 0.1, more particularly a thickness ratio of 1:0.075 to 0.092, and still more particularly a thickness ratio of 1:0.079 to 0.088. If the thickness ratio is less than 1:0.05, there may be a problem with the protection of the electrode. If the thickness ratio is more than 1:0.15, the internal resistance may increase, and the performance of the solar cell may deteriorate.

In addition, the second transparent conductive oxide layer 4 and the functional organic material layer 3 may have a thickness ratio of 1:0.05 to 0.15, particularly a thickness ratio of 1:0.066 to 0.1, more particularly a thickness ratio of 1:0.075 to 0.092, and still more particularly a thickness ratio of 1:0.079 to 0.088. If the thickness ratio is less than 1:0.05, there may be a problem with the protection of the electrode. If the thickness ratio is more than 1:0.15, the internal resistance may increase, and the performance of the solar cell may deteriorate.

Meanwhile, the first transparent conductive oxide layer 2 may have an average thickness of 5 to 100 nm, particularly 20 to 80 nm, and more particularly 30 to 70 nm. If the average thickness is less than 5 nm, there may be a problem in that the internal resistance may increase, and the performance of the solar cell deteriorates. If the average thickness is more than 100 nm, there may be a problem in that light transmissivity at a long wavelength deteriorates.

In addition, the second transparent conductive oxide layer 4 may have an average thickness of 5 to 100 nm, particularly 20 to 80 nm, and more particularly 30 to 70 nm. If the average thickness is less than 5 nm, there may be a problem in that the internal resistance may increase, and the performance of the solar cell deteriorates. If the average thickness is more than 100 nm, there may be a problem in that light transmissivity at a long wavelength deteriorates.

In addition, the functional organic material layer may have an average thickness of 2 to 50 nm, particularly 2 to 15 nm, more particularly 3 to 11 nm, still more particularly 4 to 9 nm, and most particularly 4 to 7 nm. If the average thickness is less than 2 nm, there may be a problem with the protection of the electrode. If the average thickness is more than 50 nm, there may be a problem in that the internal resistance increases, and the performance of the solar cell deteriorates.

The source electrode may be formed on the transparent conductive oxide layer by a coating or deposition process. In addition, the source electrode may include one or more selected from Pt, Au, Ni, Cu, Ag, In, Ru, Pd, Rh, Ir, Os, C, and a conductive polymer.

In addition, the solar cell of the present invention may further include a passivation layer between the light absorption layer and the electron transport layer.

The drain electrode may be made of a material including one or more selected from conductive metal, an alloy of conductive metal, a metal oxide, and a conductive polymer. In a preferred example, the drain electrode may include indium tin oxide (ITO), fluorine doped tin oxide (FTO), Sb₂O₃ doped tin oxide (ATO), gallium doped tin oxide (GTO), tin doped zinc oxide (ZTO), gallium doped ZTO (ZTO:Ga), indium gallium zinc oxide (IGZO), indium doped zinc oxide (IZO), aluminum doped zinc oxide (AZO), and/or the like.

Meanwhile, a method of manufacturing the perovskite solar cell of the present invention may include a first step of forming the transparent conductive oxide layer, by the deposition process, on the electron transport layer of the stack made by sequentially stacking the hole transport layer, the perovskite light absorption layer, and the electron transport layer, and a second step of forming the source electrode on the transparent conductive oxide layer. The transparent conductive oxide layer may include one or more of the semiconducting organic material having the pi-orbital electrons, the organic material containing the element having the unshared electron pair, and the organic material having the ionic functional group.

Specifically, the first step of the method of manufacturing the perovskite solar cell of the present invention may include a first-first step of forming a first transparent conductive oxide layer, by a deposition process, on the electron transport layer of the stack made by sequentially stacking the hole transport layer, the perovskite light absorption layer, and the electron transport layer, a first-second step of forming the functional organic material layer on the first transparent conductive oxide layer by a deposition or solution process, and a first-third step of forming the first transparent conductive oxide layer on the functional organic material layer by a deposition process. A specific description of each of the layers is identical to that described above.

Hereinafter, the present invention will be more particularly described with reference to examples, but the following examples are not intended to limit the scope of the present invention and are to be construed to assist in understanding the present invention.

### Preparation Example 1: Preparation of Transparent Conductive Oxide Film

A cleaned bare glass substrate was prepared, and the first transparent conductive oxide layer having an average thickness of 60 nm was formed by depositing indium doped zinc oxide (IZO) on the glass substrate by the sputtering process.

Next, the functional organic material layer having an average thickness of 5 nm was formed by depositing C₆₀ fullerene on the first transparent conductive oxide layer by the vacuum deposition process.

Next, the transparent conductive oxide film was prepared by forming the second transparent conductive oxide layer having an average thickness of 60 nm by depositing indium doped zinc oxide (IZO) on the functional organic material layer by the sputtering process.

### Comparative Preparation Example 1: Preparation of Transparent Conductive Oxide Film

A cleaned bare glass substrate was prepared, and a transparent conductive oxide film having an average thickness of 120 nm was formed by depositing indium doped zinc oxide (IZO) on the glass substrate by the sputtering process.

### Experimental Example 1: Measurement of Surface Resistance and Light Transmittance

In order to identify electrical and optical characteristics of the transparent conductive oxide films prepared in Preparation Example 1 and Comparative Preparation Example 1, the transparent conductive oxide films prepared in Preparation Example 1 and Comparative Preparation Example 1 were respectively stacked on the surfaces of the bare glasses, light transmittance (FIG. 2) in areas of 350 nm to 1200 nm was measured by using a UV-Vis spectroscopy, and surface resistance of the transparent conductive oxide films was measured by using a 4-point probe method. The measurement result is shown in Table 1 below.

TABLE 1

| | Surface Resistance | Light |
|---|---|---|
| Classification | (Ω/sq) | Transmittance (%) |
| Preparation | 37.71 | 89.11 |
| Example 1 | | |
| Comparative | 41.83 | 89.54 |
| Preparation | | |
| Example 1 | | |

It can be ascertained in Table 1 that the transparent conductive oxide film prepared in Preparation Example 1 and the transparent conductive oxide film prepared in Comparative Preparation Example 1 have similar surface resistance and light transmittance. Therefore, in general, it can be ascertained that because the transparent conductive oxide film prepared in Preparation Example 1 and the transparent conductive oxide film prepared in Comparative Preparation Example 1 have similar electrical and optical characteristics, the performance of the solar cell does not deteriorate even though the transparent conductive oxide film prepared in Preparation Example 1 is used for the solar cell that uses the transparent conductive oxide film prepared in Comparative Preparation Example 1.

### Example 1: Preparation of Tandem Silicon/Perovskite Heterojunction Solar Cell

As a lower solar cell, a silicon solar cell, which was doped with n or p-type impurities, was treated with hydrofluoric acid to remove an SiOx oxide film, and then residual hydrofluoric acid was removed by using ultrapure water. A recombination layer was thinly formed, by a sputtering process, at an upper end of the silicon solar cell from which the oxide film was removed.

Next, a hole transport layer (NiOx/organic material) having a thickness of 30 nm was formed on the silicon solar cell by an E-beam vacuum deposition process and a spin coating process.

Next, a yellow light absorption layer solution, which was formed by dissolving dimethylformamide (DMF) and dimethyl sulfoxide (DMSO), was formed on the hole transport layer by spin coating and subjected to heat treatment at 100° C. for 20 minutes, such that a perovskite light absorption layer (CSMAFAPbIₓBr₃₋ₓ (0≤x≤3)) having a NiOx hole transport layer and a perovskite crystal structure having a thickness of 450 to 900 nm was formed.

Next, an electron transport layer having an average thickness of 20 nm was formed by depositing C₆₀ fullerene on the perovskite light absorption layer by vacuum deposition and depositing SnOₓ on the perovskite light absorption layer on which C₆₀ fullerene was deposited by an atomic layer deposition (ALD) process.

Next, the first transparent conductive oxide layer having an average thickness of 60 nm was formed by depositing indium doped zinc oxide (IZO) on the electron transport layer by the sputtering process.

Next, the functional organic material layer having an average thickness of 5 nm was formed by depositing C₆₀ fullerene on the first transparent conductive oxide layer by the vacuum deposition process.

Next, the second transparent conductive oxide layer having an average thickness of 60 nm was formed by depositing indium doped zinc oxide (IZO) on the functional organic material layer by the sputtering process.

Next, the tandem silicon/perovskite heterojunction solar cell having a shape in which the silicon solar cell, the recombination layer, the hole transport layer, the perovskite light absorption layer, the electron transport layer, the first transparent conductive oxide layer, the functional organic material layer, the second transparent conductive oxide layer, and the source electrode were sequentially stacked was prepared by forming a source electrode by depositing silver (Ag) with a thickness of 100 nm on the second transparent conductive oxide layer at pressure of 1×10⁻⁷ torr.

### Example 2: Preparation of Tandem Silicon/Perovskite Heterojunction Solar Cell

A tandem silicon/perovskite heterojunction solar cell was prepared by the same method as Example 1. However, unlike Example 1, the functional organic material layer with an average thickness of 5 nm was formed by depositing polyethylenimine ethoxylated (PEIE) on the first transparent conductive oxide layer by the spin coating process, such that the tandem silicon/perovskite heterojunction solar cell was finally prepared.

### Comparative Example 1: Preparation of Tandem Silicon/Perovskite Heterojunction Solar Cell

As a lower solar cell, a silicon solar cell, which was doped with n or p-type impurities, was treated with hydrofluoric acid to remove an SiOx oxide film, and then residual hydrofluoric acid was removed by using ultrapure water. A recombination layer was thinly formed, by a sputtering process, at an upper end of the silicon solar cell from which the oxide film was removed.

Next, a hole transport layer (NiOx/organic material) having a thickness of 30 nm was formed on the silicon solar cell by an E-beam vacuum deposition process and a spin coating process.

Next, a yellow light absorption layer solution, which was formed by dissolving dimethylformamide (DMF) and dimethyl sulfoxide (DMSO), was formed on the hole transport layer by spin coating and subjected to heat treatment at 100° C. for 20 minutes, such that a perovskite light absorption layer (CSMAFAPbIₓBr₃₋ₓ (0≤x≤3)) having a NiOx hole transport layer and a perovskite crystal structure having a thickness of 450 to 900 nm was formed.

Next, an electron transport layer having an average thickness of 20 nm was formed by depositing C₆₀ fullerene on the perovskite light absorption layer by vacuum deposition and depositing SnOₓ on the perovskite light absorption layer on which C₆₀ fullerene was deposited by an atomic layer deposition (ALD) process.

Next, the transparent conductive oxide layer having an average thickness of 120 nm was formed by depositing indium doped zinc oxide (IZO) on the electron transport layer by the sputtering process.

Next, the tandem silicon/perovskite heterojunction solar cell having a shape in which the silicon solar cell, the recombination layer, the hole transport layer, the perovskite light absorption layer, the electron transport layer, the transparent conductive oxide layer, and the source electrode were sequentially stacked was prepared by forming a source electrode by depositing silver (Ag) with a thickness of 100 nm on the transparent conductive oxide layer at pressure of 1×10⁻⁷ torr.

### Experimental Example 2: Measurement of Performance and Long-Term Storage Stability of Solar Cell

Efficiency of the tandem silicon/perovskite heterojunction solar cells prepared in Examples 1 and 2 and Comparative Example 1 was measured by using solar simulator equipment, JV Keithley equipment, and initial JV curves. Thereafter, the tandem silicon/perovskite heterojunction solar cells were stored in a desiccator for 14 days, the JV curves were measured, and then changes in solar cell properties were measured after aging. The measurement result is shown in Table 2 below.

TABLE 2

| | Aging | Open | Short-Circuit | Fill | Photoelectric | |
|---|---|---|---|---|---|---|
| | Time | Voltage | Current Density | Factor | Conversion | Reduction |
| Classification | (day) | (V_{oc}, V) | (J_{sc}, mA/cm²) | (FF) | Efficiency (%) | Rate (%) |
| Ex. 1 | 1 | 1.844 | 18.81 | 76.72 | 26.61 | −10.3 |
| | 14 | 1.827 | 19.01 | 68.75 | 23.87 | |
| Ex. 2 | 1 | 1.834 | 19.36 | 75.48 | 26.8 | 0.04 |
| | 14 | 1.849 | 19.58 | 74.08 | 26.81 | |
| Com. Ex. 1 | 1 | 1.842 | 19.44 | 74.07 | 26.53 | −17.94 |
| | 14 | 1.813 | 19.56 | 61.37 | 21.77 | |

It can be ascertained in Table 2 that the tandem silicon/perovskite heterojunction solar cells prepared in Examples 1 and 2 have higher long-term stability than the tandem silicon/perovskite heterojunction solar cell prepared in Comparative Example 1.

The particular embodiment has been illustrated and described above. However, the present invention is not limited to the foregoing embodiments, and those skilled in the art will recognize that various modifications can be made without departing from the technical spirit of the present invention as set forth in the following claims.

1. A perovskite solar cell comprising:
a stack in which a hole transport layer, a perovskite light absorption layer, an electron transport layer, and a source electrode are sequentially stacked, wherein a transparent conductive oxide layer is formed between the source electrode and the electron transport layer, and wherein the transparent conductive oxide layer comprises one or more of a semiconducting organic material having a pi-orbital electron, an organic material containing an element having an unshared electron pair, and an organic material having an ionic functional group.

2. The perovskite solar cell of claim 1, wherein the transparent conductive oxide layer has a structure in which a first transparent conductive oxide layer, a functional organic material layer, and a second transparent conductive oxide layer are sequentially stacked.

3. The perovskite solar cell of claim 2, wherein the first transparent conductive oxide layer and the second transparent conductive oxide layer are each a transparent thin-film on which indium tin oxide (ITO), fluorine doped tin oxide (FTO), Sb₂O₃ doped tin oxide (ATO), gallium doped tin oxide (GTO), tin doped zinc oxide (ZTO), gallium doped ZTO (ZTO:Ga), indium gallium zinc oxide (IGZO), indium doped zinc oxide (IZO), or aluminum doped zinc oxide (AZO) is deposited, wherein the functional organic material layer is a thin film on which the semiconducting organic material having the pi-orbital electron, the organic material containing the element having the unshared electron pair, or the organic material having the ionic functional group is deposited, wherein the semiconducting organic material having the pi-orbital electron comprises one or more selected from fullerene, a fullerene-based derivative, perylene diimide (PDI), and naphthalene diimide (NDI), wherein the organic material containing the element having the unshared electron pair is an organic material containing one or more elements selected from oxygen, nitrogen, and phosphorus, and wherein the organic material having the ionic functional group comprises one or more selected from polyethylenimine ethoxylated (PEIE) and PFN (poly[(9, 9-di(3,3′-N,N′-trimethyl-ammonium) propylfluorenyl-2,7-diyl)-alt-co-(9,9-dioctylfluorenyl-2,7-diyl)] diiodide salt).

4. The perovskite solar cell of claim 2, wherein the first transparent conductive oxide layer and the functional organic material layer have a thickness ratio of 1:0.05 to 0.15, and the second transparent conductive oxide layer and the functional organic material layer have a thickness ratio of 1:0.05 to 0.15.

5. The perovskite solar cell of claim 2, wherein the first transparent conductive oxide layer and the second transparent conductive oxide layer each have an average thickness of 5 to 100 nm, and the functional organic material layer has an average thickness of 2 to 50 nm.

6. The perovskite solar cell of claim 1, wherein the perovskite solar cell is a p-i-n structured perovskite solar cell, an n-i-p inverse structured perovskite solar cell, a tandem perovskite solar cell, or a tandem silicon/perovskite heterojunction solar cell.

7. The perovskite solar cell of claim 6, wherein the transparent conductive oxide layer has light transmittance of 70 to 99% with respect to a wavelength of 350 to 1200 nm and has surface resistance of 5 to 500 Ω/sq.

8. A method of manufacturing a perovskite solar cell, the method comprising:
a first step of forming a transparent conductive oxide layer, by a deposition process, on an electron transport layer of a stack in which a hole transport layer, a perovskite light absorption layer, and the electron transport layer are sequentially stacked; and
a second step of forming a source electrode on the transparent conductive oxide layer, wherein the transparent conductive oxide layer comprises one or more of a semiconducting organic material having a pi-orbital electron, an organic material containing an element having an unshared electron pair, and an organic material having an ionic functional group.

9. The method of claim 8, wherein the first step comprises:
a first-first step of forming a first transparent conductive oxide layer, by the deposition process, on the electron transport layer of the stack in which the hole transport layer, the perovskite light absorption layer, and the electron transport layer are sequentially stacked;
a first-second step of forming a functional organic material layer on the first transparent conductive oxide layer by a deposition or solution process; and
a first-third step of forming a second transparent conductive oxide layer on the functional organic material layer by the deposition process.

10. A tandem silicon/perovskite heterojunction solar cell comprising:
a stack in which a drain electrode, a silicon solar cell, a recombination layer, a hole transport layer, a perovskite light absorption layer, an electron transport layer, and a source electrode are sequentially stacked, wherein a transparent conductive oxide layer is formed between the source electrode and the electron transport layer, and wherein the transparent conductive oxide layer comprises one or more of a semiconducting organic material having a pi-orbital electron, an organic material containing an element having an unshared electron pair, and an organic material having an ionic functional group.
